(19) United States
(12) Patent Application Publication
(10) Pub. No.: US 2018/0166653 A1
(43) Pub. Date: Jun. 14, 2018

(54) ORGANIC LIGHT-EMITTING DIODE DEVICE AND MANUFACTURING METHOD THEREOF

(71) Applicants: Zaifeng Xie, Shenzhen (CN); Da Huang, Shenzhen (CN); Chenhui Cao, Shenzhen (CN)

(72) Inventors: Zaifeng Xie, Shenzhen (CN); Da Huang, Shenzhen (CN); Chenhui Cao, Shenzhen (CN)

(73) Assignee: AAC Technologies Pte. Ltd., Singapore city (SG)

(21) Appl. No.: 15/416,327

(22) Filed: Jan. 26, 2017

(30) Foreign Application Priority Data
Dec. 8, 2016 (CN) 201611121683.1

(51) Int. Cl. H01L 51/52; H01L 51/56

(52) U.S. Cl. CPC H01L 51/5259; H01L 51/56

(57) ABSTRACT

An organic light-emitting diode and method for manufacturing the same is provided in the present disclosure. The organic light-emitting diode includes a base plate, an OLED unit which disposed on the base plate and a packaging structure which connected with the base plate and used for packaging the OLED unit. The packaging structure comprises a first inorganic blocking layer wrapping the OLED unit, an inorganic nano-organic copolymer mixed layer wrapping the first inorganic blocking layer and a second inorganic blocking layer wrapping the inorganic nano-organic copolymer mixed layer..

### FIELD OF THE DISCLOSURE

The present disclosure relates to the technical field of light-emitting diodes and, and more particularly, to an organic light-emitting diode (OLED) device and a manufacturing method thereof.

### BACKGROUND

An OLED has become a new generation of a flat panel display technology. The organic light-emitting diode device mainly includes a base plate, an OLED unit disposed on the base plate and a packaging structure for packaging the OLED unit. The packaging structure is used for blocking permeation of water oxygen molecules to prevent the OLED unit from being damaged.

The OLED unit is generally packaged by adopting two modes: a packaging cover packaging technology and a film packaging technology. The film packaging technology has the characteristics of lightness, thinness and flexibility over the packaging cover packaging technology, and is thus increasingly widely applied in the OLED packaging technology.

In a relevant technology, the film packaging technology includes the operations of depositing a first inorganic film for packaging an OLED unit on a conductive base plate, then coating the first inorganic film with an organic film by ink-jet printing or spraying and curing it, and finally depositing a second inorganic film on the surface of the organic film. However, the film packaging technology cannot completely solve the problem of water oxygen permeation. First, the inorganic film is formed by a CVD (Chemical Vapor Deposition) film forming process, specifically by a chemical vapor deposition reaction initiated by plasma, active molecules are diffused and adsorbed on the base plate to form islands so as to form a continuous film, and the process inevitably produces pin holes and gaps to reduce the water vapor blocking capability; Second, the gas molecule permeability of the organic film is too high. To solve the problem of water oxygen permeation of the film packaging technology, it needs to increase laminates of the whole film packaging layer to delay the time of gas molecule permeation and also needs to increase the thickness of the organic film to further improve the product reliability, the organic film with the thickness of 10-15 μm can achieve the commercial application effect in practical application, as a result, the production cost of the present OLED industry is too high, and the process is complex. Besides, in the film packaging technology, the inorganic film and the organic film in two different phases are poor in interfacial bonding capacity and easy to drop, thereby further aggravating the problem of water oxygen permeation.

Accordingly, it is necessary to provide a OLED and method for manufacturing the same to overcome the aforesaid problems.

### BRIEF DESCRIPTION OF THE DRAWINGS

Many aspects of the embodiments can be better understood with reference to the following drawings. The components in the drawing are not necessarily drawn to scale, the emphasis instead being placed upon clearly illustrating the principles of the present disclosure. Moreover, in the drawings, like reference numerals designate corresponding parts throughout the several views.

FIG. 1 is a structural schematic diagram of an organic light-emitting diode device provided by the present disclosure;

FIG. 2 is a structural schematic diagram of an inorganic nano-organic copolymer mixed layer in the organic light-emitting diode device shown in FIG. 1; and

FIG. 3 is a water oxygen blocking principle diagram of a packaging structure in the organic light-emitting diode device shown in FIG. 1.

### DETAILED DESCRIPTION

Reference will now be made to describe one embodiment of the present invention in detail.

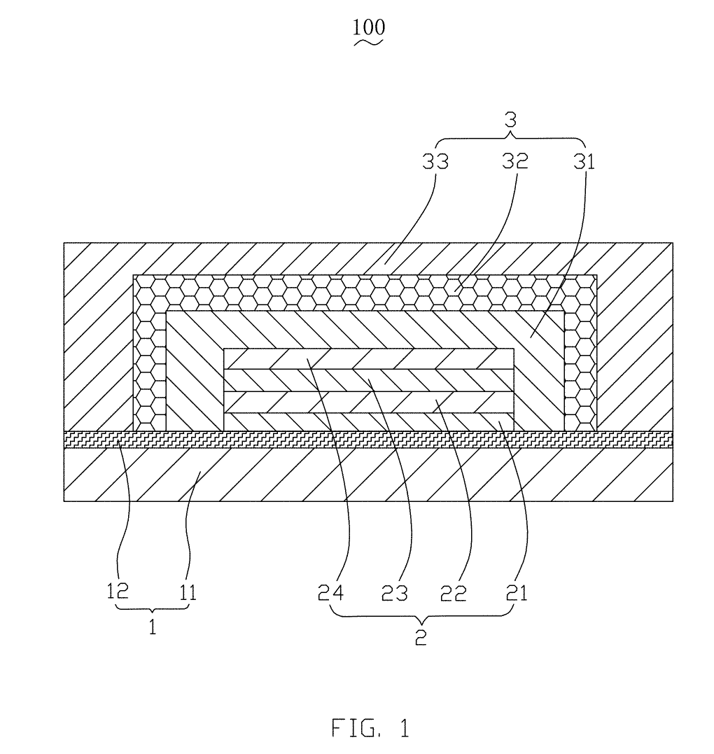

Referring to FIG. 1, FIG. 1 shows an organic light-emitting diode device 100, in accordance with an exemplary embodiment of the present invention. The organic light-emitting diode device 100 includes a base plate 1, an OLED unit 2 disposed on the base plate 1 and a packaging structure 3, wherein the packaging structure 3 is connected with the base plate 1 and used for packaging the OLED unit 2.

The base plate 1 includes a substrate 11 and a conductive anode 12 deposited on the substrate 11. The substrate 11 is a rigid substrate or a flexible substrate, wherein the rigid substrate is made of glass, a silicon chip or other rigid material; and the flexible substrate is made of plastic, an aluminum foil, ultrathin metal or ultrathin glass. The conductive anode 12 is made of ITO (Indium Tin Oxides), graphene, indium gallium zinc oxide or other conductive material, and is deposited on the surface of the substrate 11 by sputtering, evaporation and the like.

The OLED unit 2 includes a hole transport layer 21, a light-emitting layer 22, an electron transport layer 23 and a cathode 24 stacked in sequence, wherein the cathode 24 is electrically connected with the conductive anode 12.

The packaging structure 3 includes a first inorganic blocking layer 31 wrapping the OLED unit 2, an inorganic nano-organic copolymer mixed layer 32 wrapping the first inorganic blocking layer 31 and a second inorganic blocking layer 33 wrapping the inorganic nano-organic copolymer mixed layer 32.

The first inorganic blocking layer 31 and the second inorganic blocking layer 33 are respectively formed by a physical or chemical method, which may be a sputtering, vacuum deposition, chemical vapor deposition (CVD) or atomic layer deposition (ALD) method or the like, and the thicknesses of the first inorganic blocking layer 31 and the second inorganic blocking layer 33 are 1 nm-10 μm, preferably 1 nm-1 μm.

The first inorganic blocking layer 31 is made of at least one of oxide, nitride and carbonitride; and the material for the second inorganic blocking layer 33 may be same as or different from the material for the first inorganic blocking layer 31.

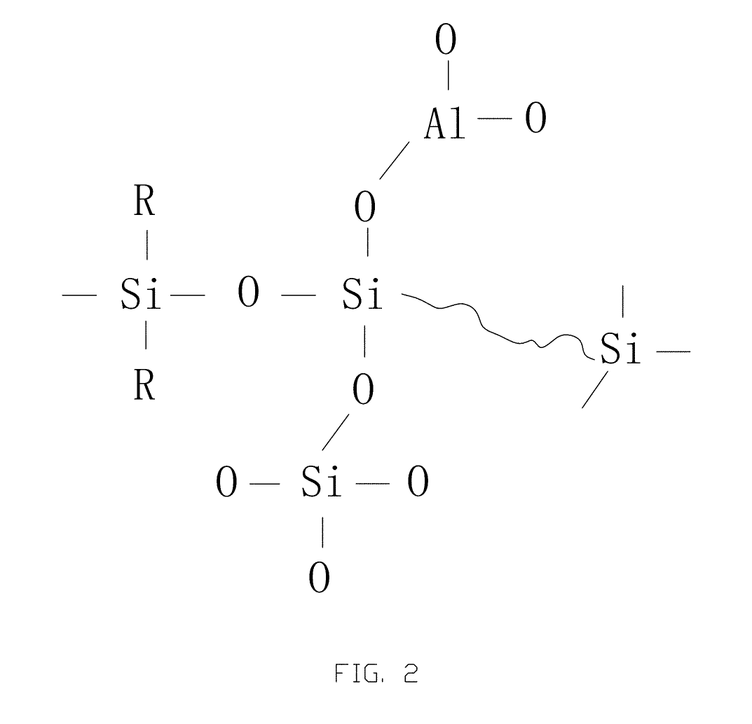

As shown in FIG. 2, which is a structural schematic diagram of an inorganic nano-organic copolymer mixed layer in the organic light-emitting diode device shown in FIG. 1, the inorganic nano-organic copolymer mixed layer 32 includes a crosslinked polymer and inorganic nano particles chelated to the crosslinked polymer by covalent bonds.

The crosslinked polymer is one of or a combination of more of a carbon chain polymer, an organic silicon polymer and a heterochain polymer; the general formula of the inorganic nano particles is MxOy or MxSy, wherein M is an I-VIA main family element or/and a transition metal element; preferably, the inorganic nano particles are at least one of TiO2, Al2O3, SiO2, Sn2O3, ZrO, TiS2, Al2S3, SiS2, SnS2 and S2Zr. The inorganic nano-organic copolymer mixed layer 32 has the characteristics of high density and high refractive index (more than 1.4) provided by the inorganic nano material and the characteristics of flexibility, high light transmittance and low stress of the organic crosslinked polymer, so that the packaging structure 3 has the characteristics of excellent water oxygen blocking capacity and good packaging effect.

Otherwise, the inorganic nano particles are not limited to the above components, and may also be other MxOy or MxSy satisfying the condition or a composition of the latter.

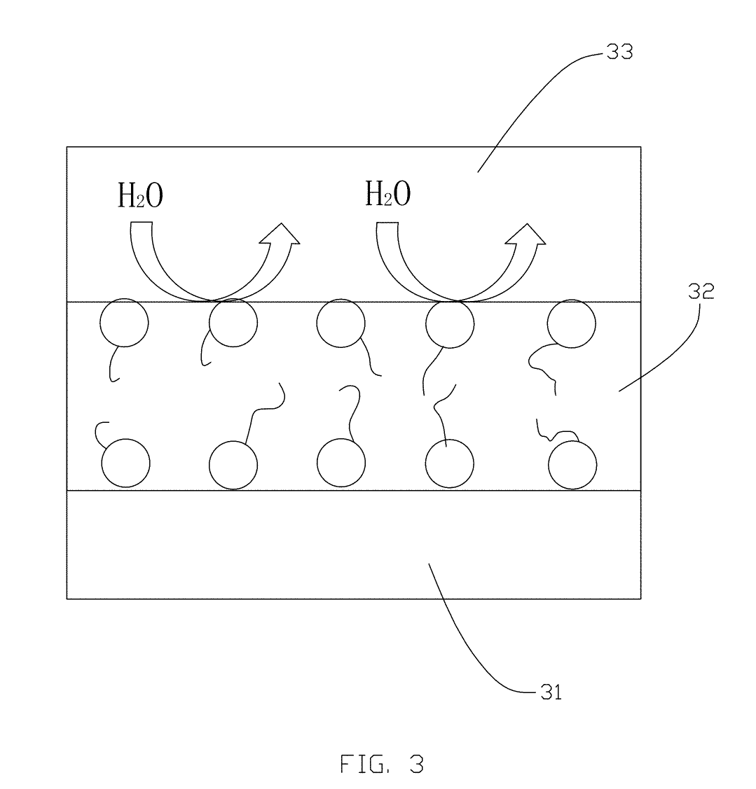

Refer to FIG. 3, which is a water oxygen blocking principle diagram of the packaging structure in the organic light-emitting diode device shown in FIG. 1, wherein circles express inorganic nano particles. When water oxygen molecules in the environment are permeated to the inorganic nano-organic copolymer mixed layer 32, the inorganic nano particles chelated to the crosslinked polymer partially or completely block direct intrusion of the water oxygen molecules, so that relatively low water vapor permeability is obtained. Thus, the thickness of the inorganic nano-organic copolymer mixed layer 32 can be greatly reduced, to meet the requirement of commercial application within the range of 1 nm-10 μm. Preferably, the thickness of the inorganic nano-organic copolymer mixed layer 32 is 1-5 μm, thereby facilitating the development and the application of the flexible OLED.

The present disclosure provides a manufacturing method of an organic light-emitting diode device, including the following steps:

step S1: depositing an OLED unit 2 on a base plate 1;

specifically, including pretreatment of the base plate: firstly, cleaning the base plate 1 with acetone or other organic solvent; then heating and baking; performing ultraviolet sterilization.

depositing the OLED unit 2 on the pretreated base plate 1: depositing a hole transport layer 21, a light-emitting layer 22, an electron transport layer 23 and a cathode 24 on the base plate 1 in sequence to form the OLED unit 2.

step S2: depositing a first inorganic blocking layer 31 on the outer surface of the OLED unit 2 to package the OLED unit 2;

specifically, depositing at least one of oxide, nitride and carbonitride on the outer surface of the OLED unit 2 by CVD, sputtering, ALD or the like to form a film with the thickness of 1 nm-10 μm, e.g., an SiOx, SiN, SiCN or TiOx film.

step S3: coating the first inorganic blocking layer 31 with an inorganic nano-organic copolymer mixture, and curing it to form an inorganic nano-organic copolymer mixed layer 32;

specifically, mixing inorganic nano particles with an organic crosslinked polymer, coating the surface of the first inorganic blocking layer 31 with the mixture by wet spin-coating to form gel containing nano particles, and then forming the inorganic nano-organic copolymer mixed layer 32 with the thickness of 1 nm-10 μm by ultraviolet curing or thermal curing,

wherein the general formula of the inorganic nano particles is MxOy or MxSy, and M is an I-VIA main family element or/and a transition metal element; preferably, the inorganic nano particles are at least one of TiO2, Al2O3, SiO2, Sn2O3, ZrO, TiS2, Al2S3, SiS2, SnS2 and S2Zr; the organic crosslinked polymer is one of or a combination of more of a carbon chain polymer, an organic silicon polymer and a heterochain polymer, and the inorganic nano particles are chelated to the organic crosslinked polymer by covalent bonds -X-O-Y or -X-S-Y; and

step S4: depositing a second inorganic blocking layer 33 on the inorganic nano-organic copolymer mixed layer 32,

specifically, the process of this step is same as that of step 2, and the material for the second inorganic blocking layer 33 is same as or different from the material for the first inorganic blocking layer 31.

The organic light-emitting diode device provided by the present disclosure has the following advantages:

Firstly, the packaging structure of the organic light-emitting diode device includes a first inorganic blocking layer, an inorganic nano-organic copolymer mixed layer and a second inorganic blocking layer disposed from inside to outside, wherein the inorganic nano-organic copolymer mixed layer has high density and high refractive index of an inorganic nano material and has flexibility, high light transmittance and low stress of an organic film, and when water oxygen molecules in the environment are permeated to the inorganic nano-organic copolymer mixed layer, the inorganic nano particles chelated to the crosslinked polymer partially or completely block direct intrusion of the water oxygen molecules, so that relatively low water vapor permeability is obtained, and the organic light-emitting diode device has the characteristic of excellent water oxygen blocking capacity;

Secondly, the inorganic nano-organic copolymer mixed layer includes a crosslinked polymer and inorganic nano particles chelated to the crosslinked polymer by covalent bonds, so that the inorganic phase is uniformly dispersed into the organic phase, the gas blocking effect and the light transmittance are guaranteed, and the performance of the organic light-emitting diode device is improved; meanwhile, the inorganic nano-organic copolymer mixed layer is bonded with the adjacent inorganic phase by covalent bonds to form more stable interfacial force, thereby preventing the film from dropping;

Then, the inorganic nano-organic copolymer mixed layer has relatively low water vapor permeability, and thickness can be reduced to be within 10 μm, thereby facilitating the development and the application of the flexible OLED; by using the inorganic nano-organic copolymer mixed layer, the packaging structure only needs three layers to meet the water oxygen blocking capacity, so that the manufacturing process is simplified, and the cost is greatly reduced; and

Finally, the inorganic nano-organic copolymer mixed layer contains nano particles with high refractive index, so that the OLED light can be extracted to obtain a high-performance light emitting performance, and the light extracting rate can be improved by 40%.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

1. An organic light-emitting diode device, comprising:
a base plate;
an OLED unit, disposed on the base plate; and
a packaging structure, connected with the base plate and used for packaging the OLED unit;
wherein the packaging structure comprises a first inorganic blocking layer wrapping the OLED unit, an inorganic nano-organic copolymer mixed layer wrapping the first inorganic blocking layer and a second inorganic blocking layer wrapping the inorganic nano-organic copolymer mixed layer.

2. The organic light-emitting diode device as described in claim 1, wherein the inorganic nano-organic copolymer mixed layer comprises a crosslinked polymer and inorganic nano particles chelated to the crosslinked polymer by covalent bonds.

3. The organic light-emitting diode device as described in claim 2, wherein the general formula of the inorganic nano particles is MxOy or MxSy, and M is an I-VIA main family element or/and a transition metal element.

4. The organic light-emitting diode device as described in claim 3, wherein the inorganic nano particles are at least one of TiO2, Al2O3, SiO2, Sn2O3, ZrO, TiS2, Al2S3, SiS2, SnS2 and S2Zr.

5. The organic light-emitting diode device as described in claim 2, wherein the refractive index of the inorganic nano particles is more than 1.4.

6. The organic light-emitting diode device as described in claim 2, wherein the crosslinked polymer is at least one of a carbon chain polymer, an organic silicon polymer and a heterochain polymer.

7. The organic light-emitting diode device as described in claim 1, wherein the thickness of the inorganic nano-organic copolymer mixed layer is 1 nm-10 μm.

8. The organic light-emitting diode device as described in claim 1, wherein the inorganic nano-organic copolymer mixed layer is formed by the steps of wet spin-coating and ultraviolet curing in sequence.

9. The organic light-emitting diode device as described in claim 1, wherein the first inorganic blocking layer and the second inorganic blocking layer are made of at least one of oxide, nitride and carbonitride.

10. The organic light-emitting diode device as described in claim 1, wherein the thicknesses of the first inorganic blocking layer and the second inorganic blocking layer are 1 nm-10 μm.

11. A manufacturing method of an organic light-emitting diode device, comprising the following steps:
providing a base plate and an OLED unit, and depositing the OLED unit on the base plate;
depositing a first inorganic blocking layer on the outer surface of the OLED unit to package the OLED unit;
coating the first inorganic blocking layer with an inorganic nano-organic copolymer mixture, and curing it to form an inorganic nano-organic copolymer mixed layer; and
depositing a second inorganic blocking layer on the inorganic nano-organic copolymer mixed layer.

12. An organic light-emitting diode deviceas described in claim 1, whereinthe inorganic nano-organic copolymer mixed layer comprises a repeating unit of Formula 1 below: 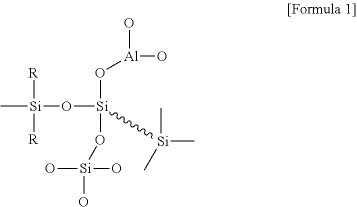
Wherein, Si is Silicon atom, Al is Aluminum atom,[—Si—O—Si-] represents inorganic nano-organic copolymer matrix,[O—Al—O] represents performance-modified inorganic unit, [—Si—R] represents based on Silicone organic unit,[R] represents organic unit.
